(19) United States
(12) Patent Application Publication
(10) Pub. No.: US 2022/0349044 A1
(43) Pub. Date: Nov. 3, 2022

(54) DEVICE FOR VAPOR DEPOSITING METAL

(71) Applicant: Shenzhen China Star Optoelectronics Semiconductor Display Technology Co., Ltd., Shenzhen (CN)

(72) Inventors: Lixia RUAN, Shenzhen (CN); Daoxu LIU, Shenzhen (CN)

(73) Assignee: Shenzhen China Star Optoelectronics Semiconductor Display Technology Co., Ltd., Shenzhen (CN)

(21) Appl. No.: 17/863,463

(22) Filed: Jul. 13, 2022

Related U.S. Application Data
(62) Division of application No. 16/765,185, filed on May 19, 2020.

(30) Foreign Application Priority Data
Apr. 9, 2020 (CN) 202010273606.8

(51) Int. Cl. C23C 14/54; C23C 14/24

(52) U.S. Cl. CPC C23C 14/54; C23C 14/243; C23C 14/246

(57) ABSTRACT

A device for vapor depositing metal is disclosed. The device includes a vapor-deposition chamber and a storage chamber. The storage chamber can be connected to the vapor-deposition chamber by an openable and closable isolating door. At least one storage unit configured to store at least one metal evaporation material is disposed in the storage chamber. At least one feeding unit in one-to-one correspondence with the at least one storage unit is disposed in the vapor-deposition chamber.

### RELATED APPLICATIONS

This application is a Divisional of pending U.S. patent application Ser. No. 16/765,185, filed May 19, 2020 and entitled “DEVICE FOR VAPOR DEPOSITING METAL”, which claims priority to Chinese patent application no. 202010273606.8 submitted to Chinese Patent Office on Apr. 9, 2020, entitled “DEVICE FOR VAPOR DEPOSITING METAL”, the entire contents of which are incorporated herein by reference.

### FILED AND BACKGROUND OF THE INVENTION

The present disclosure relates to the field of display technologies, and more particularly, relates to a device for vapor depositing metal.

Organic light-emitting diode (OLED) display devices have become a popular next-generation display technology due to advantages such as light and thin body, low power consumption, high brightness, excellent luminous efficiency, and capability for realizing flexible display.

Typically, OLED devices are manufactured by performing heating, evaporation, and deposition processes. Specifically, heating an evaporation material (may be a sublimation type or a melting type) with a heating vessel under vacuum environment, vaporizing the evaporation material at a high temperature, and then depositing it on a substrate having a thin film transistor (TFT) structure or an anode structure. Generally, multiple metals and crucibles are contained in a vapor-deposition chamber, so that various materials are able to be evaporated together. Metal materials need to be evaporated at a relatively high temperature (usually greater than 1000° C.). When one of the metal materials runs out, a temperature of the vapor-deposition chamber needs to be reduced, so that we can open it and re-add materials into it. However, changing the crucibles, re-adding the materials, and adjusting them take much time, which significantly affects production capacity.

### SUMMARY OF THE INVENTION

The present disclosure provides a device for vapor depositing metal which can effectively solve a problem of lost production capacity of device for vapor depositing metal due to adding materials.

To solve the above problem, in a first aspect, the present disclosure provides a device for vapor depositing metal, including:

a vapor-deposition chamber; and

a storage chamber, wherein the storage chamber is connected to the vapor-deposition chamber by an isolating door, and is configured to control the isolating door to open or close to realize connection or isolation between the vapor-deposition chamber and the storage chamber;

wherein at least one storage unit is disposed in the storage chamber and is configured to store at least one metal evaporation material; and

wherein at least one feeding unit in a one-to-one correspondence with the at least one storage unit and at least one evaporation crucible in a one-to-one correspondence with the at least one feeding unit are disposed in the vapor-deposition chamber, and the metal evaporation material stored in the at least one storage unit is transported to the corresponding feeding unit by the isolating door and then is transported to the corresponding evaporation crucible.

In the device for vapor depositing metal according to one embodiment of the present disclosure, the device for vapor depositing metal further includes a vacuum system that separately and individually controls vacuum degrees of the vapor-deposition chamber and the storage chamber.

In the device for vapor depositing metal according to one embodiment of the present disclosure, before the isolating door is opened, the storage chamber is vacuumized by the vacuum system, so that the vacuum degree of the storage chamber is equal to the vacuum degree of the vapor-deposition chamber.

In the device for vapor depositing metal according to one embodiment of the present disclosure, the at least one storage unit includes:

a main storage device configured to store a ball-shaped metal evaporation material;

a feeding guiding tube connected to the main storage device and configured to transport the ball-shaped metal evaporation material into the at least one feeding unit; and

a first valve disposed on the feeding guiding tube, wherein when a material is fed, the first valve is opened, and when the material is already fed, the first valve is closed.

In the device for vapor depositing metal according to one embodiment of the present disclosure, a diameter of the ball-shaped metal evaporation material ranges from 1 mm to 2 mm.

In the device for vapor depositing metal according to one embodiment of the present disclosure, a first slide rail is further disposed in the storage chamber, and the at least one storage unit is slidably connected to the first slide rail.

In the device for vapor depositing metal according to one embodiment of the present disclosure, at least one limiting block is disposed on the first slide rail, thereby confining a slidable range of the at least one storage unit.

In the device for vapor depositing metal according to one embodiment of the present disclosure, two limiting blocks are disposed on the first slide rail and separately disposed at two sides of the at least one storage unit.

In the device for vapor depositing metal according to one embodiment of the present disclosure, an open degree and an open period of the first valve is controlled according to a predetermined amount of the material.

In the device for vapor depositing metal according to one embodiment of the present disclosure, the at least one storage unit includes:

a metal wire coil formed from a wound metal wire made of the metal evaporation material; and

a guide roller configured to guide the metal wire;

A cutting device is further disposed in the vapor-deposition chamber, the cutting device receives the metal line guided by the guide roller, cuts the metal line into a plurality of metal particles, and then transports the metal particles into the at least one feeding unit.

In the device for vapor depositing metal according to one embodiment of the present disclosure, an openable and closable valve is further disposed between the cutting device and the at least one feeding unit, thereby controlling connection or isolation between the cutting device and the at least one feeding unit.

In the device for vapor depositing metal according to one embodiment of the present disclosure, a diameter of the metal particles ranges from 1 mm to 2 mm.

In the device for vapor depositing metal according to one embodiment of the present disclosure, a second slide rail horizontally wound around an inner wall of the vapor-deposition chamber is further disposed in the vapor-deposition chamber, and the at least one feeding unit is slidably connected to the second slide rail.

In the device for vapor depositing metal according to one embodiment of the present disclosure, the at least one feeding unit is slidably connected to the second slide rail by a rotary slidable guiding member, thereby allowing the at least one feeding unit to move vertically when rotating.

In the device for vapor depositing metal according to one embodiment of the present disclosure, the second slide rail includes one or more circles of slide rails which are parallel to each other in a vertical direction and are wound around the inner wall of the vapor-deposition chamber.

In the device for vapor depositing metal according to one embodiment of the present disclosure, the at least one feeding unit includes:

a secondary storage device configured to store the metal evaporation material transported from the at least one storage unit;

a feeding guiding tube connected to the secondary storage device and configured to transport the metal evaporation material in the secondary storage device into the at least one evaporation crucible; and

a second valve disposed on the feeding guiding tube, wherein when a material is fed, the first valve is opened, and when the material is already fed, the first valve is closed.

In the device for vapor depositing metal according to one embodiment of the present disclosure, the feeding guiding tube includes a first part and a second part connected to each other, the first part is straight, and the second part is smoothly curved.

In the device for vapor depositing metal according to one embodiment of the present disclosure, an internal diameter of the feeding guiding tube ranges from 2 mm to 3 mm.

In the device for vapor depositing metal according to one embodiment of the present disclosure, when the material is fed, a feeding port of the feeding guiding tube is positioned at an edge of the at least one evaporation crucible.

In the device for vapor depositing metal according to one embodiment of the present disclosure, when the material is fed, a feeding port of the feeding guiding tube is aligned with an upper surface of the at least one evaporation crucible.

Regarding the beneficial effects: compared with conventional technologies, the present disclosure provides a device for vapor depositing metal. By separating a storage chamber from a vapor-deposition chamber, when an evaporation material in the vapor depositing chamber runs out, new evaporation material can be transported into the vapor depositing chamber from the storage chamber disposed outside the vapor depositing chamber. Therefore, it is not necessary to open the vapor-deposition chamber. In addition, when a device in the storage chamber is abnormal, the abnormal device in the storage chamber can be repaired individually without affecting an evaporation process performed in the vapor-deposition chamber, which significantly improves production capacity of the vapor-deposition device.

### BRIEF DESCRIPTION OF THE SEVERAL VIEWS OF THE DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic structural view showing a device for vapor depositing metal provided by an embodiment of the present disclosure.

FIG. 2 is a schematic structural view showing another device for vapor depositing metal provided by an embodiment of the present disclosure.

FIG. 3 is a schematic structural view showing a vapor-deposition chamber of yet another device for vapor depositing metal provided by an embodiment of the present disclosure.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the present disclosure, the word “exemplary” is used herein to mean “serving as an example, instance, or illustration.” Any embodiment described herein as “exemplary” is not necessarily to be construed as preferred or advantageous over other embodiments. Descriptions are provided to make any skilled in the art able to realize and utilize the present disclosure. In the following descriptions, details are listed for the purpose of illustration. It should be noted that those skilled in the art may realize the present disclosure without using the specific details. In other embodiments, conventional structures and processes are not be illustrated in detail to prevent the illustration of the present disclosure from being complicated due to unnecessary details. Therefore, exemplary embodiments are consistent with principles and features, which are interpreted broadly, disclosed by the present disclosure but shall not be regarded as limitations of the present disclosure.

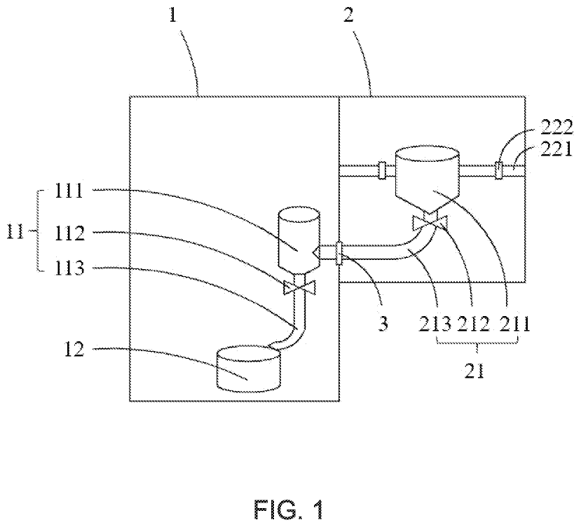

An embodiment of the present disclosure provides a device for vapor depositing metal, and a structure thereof can be referred to FIG. 1. Specifically, the device for vapor depositing metal includes:

a vapor-deposition chamber 1 where a vapor-deposition process is performed; and

a storage chamber 2, wherein the storage chamber 2 is connected to the vapor-deposition chamber 1 by an isolating door 3, and is configured to control the isolating door 3 to open or close to realize connection or isolation between the vapor-deposition chamber 1 and the storage chamber 2.

At least one storage unit 21 configured to store at least one evaporation metal material is disposed in the storage chamber 2. Each of the at least one storage unit 21 can only store a certain type of material, but cannot store multiple materials. At least one feeding unit 11 in a one-to-one correspondence with the at least one storage unit 21 and at least one evaporation crucible 12 in a one-to-one correspondence with the at least one feeding unit 11 are disposed in the vapor-deposition chamber 1. The metal evaporation material stored in the at least one storage unit 21 is transported to the corresponding feeding unit 11 by the isolating door 3 and then is transported to the corresponding evaporation crucible 12 from the feeding unit 11. When a material is fed, the isolating door 3 is opened, so that the storage unit 21 can transport the material to the feeding unit 11. When the material is already fed, the isolating door 3 is closed immediately.

Furthermore, the device for vapor depositing metal further includes a vacuum system (not shown) which respectively and individually controls vacuum degrees of the vapor-deposition chamber 1 and the storage chamber 2. Before the isolating door 3 is opened, the vacuum degree of the vapor-deposition chamber 1 and the vacuum degree of the storage chamber 2 must be equal.

Please continue to refer to FIG. 1, in one embodiment, the at least one storage unit 21 includes:

a main storage device 211 configured to store a ball-shaped metal evaporation material, wherein a diameter of the ball-shaped metal evaporation material generally ranges from 1 mm to 2 mm;

a feeding guiding tube 213 connected to the main storage device 211 and configured to transport the ball-shaped metal evaporation material into the at least one feeding unit 11; and

a first valve 212 disposed on the feeding guiding tube 213 and configured to open or close the feeding guiding tube 213, wherein when a material is fed, the first valve 212 is opened, and when the material is already fed, the first valve 212 is closed.

Furthermore, a first slide rail 221 is further disposed in the storage chamber 2, and the at least one storage unit 21 is slidably connected to the first slide rail 221, so that it can slide toward or away from the vapor-deposition chamber 1. An amount of the first slide rail 221 corresponds to an amount of the at least one storage unit 21.

Furthermore, at least one limiting block 222 is disposed on the first slide rail, thereby confining a slidable range of the at least one storage unit 21. Generally, two limiting blocks 222 are disposed on each first slide rail 221 and are disposed at two sides of the at least one storage unit 21.

When a material is added into the vapor-deposition chamber 1, the isolating door 3 is opened, and the at least one storage unit 21 is moved to the far-left side by the first slide rail. Finally, the first valve 212 is opened, so that the material can be added. An open degree and an open period of the first valve can be controlled according to a predetermined amount of the material.

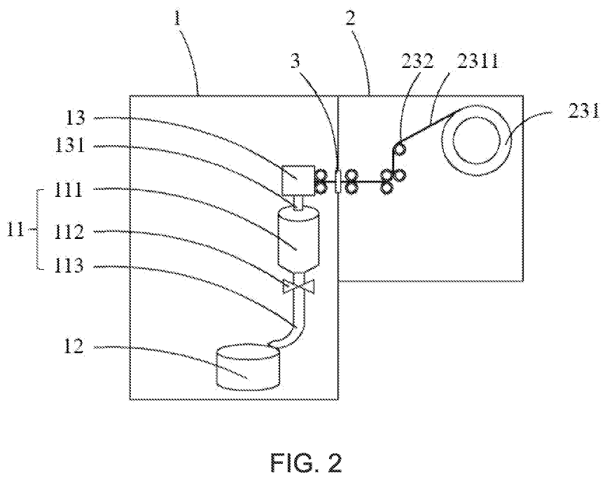

Please refer to FIG. 2, another embodiment of the present disclosure further provides a device for vapor depositing metal, a structure thereof is roughly similar to the structure of the device for vapor depositing metal mentioned in the above embodiment, and the only difference therebetween is their storage unit's structure. Specifically, in the present embodiment, the at least one storage unit includes:

a metal wire coil 231 formed from a corresponding wound metal wire 2311 made of the metal evaporation material; and

a guide roller 232 configured to transport the metal wire 2311 into the vapor-deposition chamber 1 by rotating itself.

Furthermore, a cutting device 13 is further disposed in the vapor-deposition chamber 1. The cutting device 13 receives the metal wire 2311 transported from the guide roller 232, and cuts the metal wire 2311 into multiple metal particles. Then, a valve 131 is opened, so that the metal particles are able to be transported to the at least one feeding unit 111. The valve is disposed between the cutting device 13 and the feeding unit 111. By controlling (opening or closing) the valve 131, the cutting device 13 and the at least one feeding unit 111 can be connected or isolated. Typically, the cutting device 13 cuts the metal wire 2311 into multiple ball-shaped metal particles, and a diameter of the ball-shaped metal particles usually ranges from 1 mm to 2 mm.

When a material is added into the vapor-deposition chamber 1, the isolating door 3 is opened. Then, the guide roller 232 starts rotating to transport the metal wire 2311 to the cutting device 13 in the vapor-deposition chamber 1. After the metal line 2311 is cut into multiple metal particles by the cutting device, the valve 131 is opened, and the metal particles are transported to the at least one feeding unit 11.

Please continue to refer to FIG. 1, in the device for vapor depositing metal, the at least one feeding unit 11 includes:

a secondary storage device 111 configured to store the metal evaporation material transported from the at least one storage unit, wherein the secondary storage device 111 has a certain capacity, thereby preventing production capacity from being affected due to interruption of material caused by abnormal storage chamber 2. According to an actual production requirement, the secondary storage device 111 can usually store at least two days' worth of the production material;

a feeding guiding tube 113 connected to the secondary storage device 111 and configured to transport the metal evaporation material in the secondary storage device 111 into the at least one evaporation crucible 12; and

a second valve 112 disposed on the feeding guiding tube 113 and configured to open or close the feeding guiding tube 113, wherein when a material is fed, the first valve is opened, and when the material is already fed, the first valve is closed.

Moreover, the feeding guiding tube 113 is bent to be J-shaped and includes a first part and a second part connected to each other. The first part is straight and is directly connected to the secondary storage device 111. The second part is smoothly curved and has a smooth inner wall, and is a feeding port that directly feeds the material into the at least one evaporation crucible 12. When the material is fed, the feeding port of the feeding guiding tube is aligned with an upper surface of the at least one evaporation crucible and is positioned at an edge of the at least one evaporation crucible, thereby preventing the feeding port from being blocked by the evaporation material.

Furthermore, an internal diameter of the feeding guiding tube 113 usually ranges from 2 mm to 3 mm, and only one particle of the evaporation material is permitted to pass through the feeding guiding tube 113 at one time, thereby preventing the feeding guiding tube 113 from being blocked.

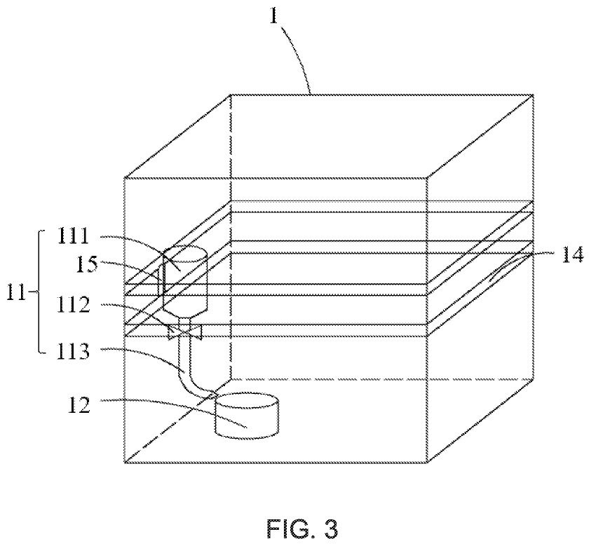

Because one type of evaporation material usually corresponds to multiple evaporation crucibles disposed at different positions in a vapor-deposition chamber, a feeding process needs to be improved. Therefore, yet another embodiment of the present disclosure further provides a device for vapor depositing metal that has a vapor-deposition chamber with an improved structure. The improved structure is shown in FIG. 3, a second slide rail 14 horizontally wound around an inner wall of the vapor-deposition chamber is further disposed in the vapor-deposition chamber 1, and the at least one feeding unit 11 is slidably connected to the second slide rail 14, thereby allowing at least one feeding unit 11 to slide 360 degrees along the inner wall of the vapor-deposition chamber 1. In other words, multiple evaporation crucibles corresponding to the same material at different positions can be fed by a single feeding unit 11, thereby simplifying a structure of the device.

Furthermore, the at least one feeding unit 11 is slidably connected to the second slide rail 14 by a rotary slidable guiding member 15, thereby allowing the at least one feeding unit 11 to slide along the second slide rail 14 and move vertically. When the material is fed, the feeding guiding tube 113 is aligned with the at least one evaporation crucible 12. When the material is already fed, the rotary guiding member 15 is rotated, so that at least one feeding unit 11 can move vertically when rotating, thereby effectively preventing the feeding port of the feeding guiding tube 113 from being blocked by the evaporation material.

Furthermore, the second slide rail 14 is wound around the inner wall of the vapor-deposition chamber 1 and includes one or more circles of slide rails (not shown) which are parallel to each other in a vertical direction and are wound around the inner wall of the vapor-deposition chamber. The feeding units with different materials are connected to different slide rails, thereby preventing slidable range from being interfered with by each other.

In the above embodiments, the focus of each embodiment is different, and for a part that is not detailed in an embodiment, reference may be made to related descriptions of other embodiments.

In specific implementations, each of the above units or structures may be implemented independently or may be combined as one, several entities, or any combination to realize the present disclosure. Implementations of each of the above units or structures may be understood with reference to the above embodiments and will not be described again here.

A device for vapor depositing metal has been described in detail with embodiments provided by the present disclosure which illustrates principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A device for vapor depositing metal, comprising:
a vapor-deposition chamber; and
a storage chamber, wherein the storage chamber is connected to the vapor-deposition chamber by an isolating door, and is configured to control the isolating door to open or close to realize connection or isolation between the vapor-deposition chamber and the storage chamber;
wherein at least one storage unit is disposed in the storage chamber and is configured to store at least one metal evaporation material; and
wherein at least one feeding unit in a one-to-one correspondence with the at least one storage unit and at least one evaporation crucible in a one-to-one correspondence with the at least one feeding unit are disposed in the vapor-deposition chamber, and the metal evaporation material stored in the at least one storage unit is transported to the corresponding feeding unit by the isolating door and then is transported to the corresponding evaporation crucible.

2. The device for vapor depositing metal of claim 1, further comprising a vacuum system that separately and individually controls vacuum degrees of the vapor-deposition chamber and the storage chamber.

3. The device for vapor depositing metal of claim 2, wherein before the isolating door is opened, the storage chamber is vacuumized by the vacuum system, so that the vacuum degree of the storage chamber is equal to the vacuum degree of the vapor-deposition chamber.

4. The device for vapor depositing metal of claim 1, wherein a second slide rail horizontally wound around an inner wall of the vapor-deposition chamber is further disposed in the vapor-deposition chamber, and the at least one feeding unit is slidably connected to the second slide rail.

5. The device for vapor depositing metal of claim 4 wherein the at least one feeding unit is slidably connected to the second slide rail by a rotary slidable guiding member, thereby allowing the at least one feeding unit to move vertically when rotating.

6. The device for vapor depositing metal of claim 4, wherein the second slide rail comprises one or more circles of slide rails which are parallel to each other in a vertical direction and are wound around the inner wall of the vapor-deposition chamber.

7. The device for vapor depositing metal of claim 1, wherein the at least one feeding unit comprises:
a secondary storage device configured to store the metal evaporation material transported from the at least one storage unit;
a feeding guiding tube connected to the secondary storage device and configured to transport the metal evaporation material in the secondary storage device into the at least one evaporation crucible; and
a second valve disposed on the feeding guiding tube, wherein when a material is fed, the first valve is opened, and when the material is already fed, the first valve is closed.

8. The device for vapor depositing metal of claim 7, wherein the feeding guiding tube comprises a first part and a second part connected to each other, the first part is straight, and the second part is smoothly curved.

9. The device for vapor depositing metal of claim 7, wherein an internal diameter of the feeding guiding tube ranges from 2 mm to 3 mm.

10. The device for vapor depositing metal of claim 7, wherein when the material is fed, a feeding port of the feeding guiding tube is positioned at an edge of the at least one evaporation crucible.

11. The device for vapor depositing metal of claim 7, wherein when the material is fed, a feeding port of the feeding guiding tube is aligned with an upper surface of the at least one evaporation crucible.
